(19) United States
(12) Patent Application Publication
(10) Pub. No.: US 2025/0301574 A1
(43) Pub. Date: Sep. 25, 2025

(54) CIRCUIT BOARD

(71) Applicant: TAIYO YUDEN CO., LTD., Tokyo (JP)

(72) Inventor: Ayumi SHIROTA, Tokyo (JP)

(73) Assignee: TAIYO YUDEN CO., LTD., Tokyo (JP)

(21) Appl. No.: 19/231,713

(22) Filed: Jun. 9, 2025

Related U.S. Application Data
(63) Continuation of application No. PCT/JP2023/045910, filed on Dec. 21, 2023.

(30) Foreign Application Priority Data
Dec. 23, 2022 (JP) 2022-207282

(51) Int. Cl. H05K 1/18; H01G 4/01; H01G 4/12; H01G 4/30; H05K 1/11

(52) U.S. Cl. CPC H05K 1/181; H01G 4/01; H01G 4/12; H01G 4/30; H05K 1/111; H05K 2201/10015; H05K 2201/10522; H05K 2201/10628; H05K 2201/10757

(57) ABSTRACT

A circuit board includes a board, a multilayer ceramic electronic component mounted on a mounting surface of the board, and an electronic component that is adjacent to the multilayer ceramic electronic component and mounted on the mounting surface of the board. A mounting area of the multilayer ceramic electronic component on the board is 1/10 or less of a mounting area of the electronic component on the board. A dimension of the multilayer ceramic electronic component in a direction along a first axis orthogonal to the mounting surface is 1.3 times or more a dimension of the multilayer ceramic electronic component in a direction along a second axis orthogonal to the first axis.

### CROSS-REFERENCE TO RELATED APPLICATION

This application is a continuation application of PCT/JP2023/045910 filed on Dec. 21, 2023, which claims priority to Japanese Patent Application No. 2022-207282 filed on Dec. 23, 2022, the contents of which are herein wholly incorporated by reference.

### FIELD

A certain aspect of the present invention relates to a circuit board.

### BACKGROUND

In recent years, various electronic devices have become smaller and more functional, and a large number of electronic components are being densely mounted on a circuit board. These electronic components are mounted on a land formed on a printed wiring board using solder paste. The solder paste is printed on the land using a screen printing mask with openings formed to match the position and shape of the lands (see, for example, Japanese Patent Application Publication No. 2018-6465). Such a mask can also be used when mounting multiple electronic components adjacent to each other on a printed wiring board.

### SUMMARY OF THE INVENTION

According to an aspect of the present invention, there is provided a circuit board including: a board; a multilayer ceramic electronic component mounted on a mounting surface of the board; and an electronic component that is adjacent to the multilayer ceramic electronic component and mounted on the mounting surface of the board, wherein a mounting area of the multilayer ceramic electronic component on the board is 1/10 or less of a mounting area of the electronic component on the board, and wherein a dimension of the multilayer ceramic electronic component in a direction along a first axis orthogonal to the mounting surface is 1.3 times or more a dimension of the multilayer ceramic electronic component in a direction along a second axis orthogonal to the first axis.

### BRIEF DESCRIPTION OF THE DRAWINGS

FIG. 1A is a side view of a circuit board of a first embodiment;

FIG. 1B and FIG. 1C illustrate a relationship between a dimension of a multilayer ceramic capacitor and a dimension of a land;

FIG. 2 is a perspective view of a first multilayer ceramic capacitor used in a circuit board of a first embodiment;

FIG. 3 is a perspective view of a second multilayer ceramic capacitor used in a circuit board of a first embodiment;

FIG. 4A is an explanatory diagram illustrating a mounting area of a first multilayer ceramic capacitor used in a circuit board of a first embodiment;

FIG. 4B is an explanatory diagram illustrating a mounting area of a second multilayer ceramic capacitor used in a circuit board of a first embodiment;

FIG. 5A to FIG. 5D are a four-sided view of a first multilayer ceramic capacitor used in a circuit board of a first embodiment;

FIG. 6 is a cross-sectional view taken along a line A1-A1 in FIG. 2 of a first multilayer ceramic capacitor used in a circuit board of a first embodiment;

FIG. 7A is a cross-sectional view taken along a line A2-A2 in FIG. 2 of a first multilayer ceramic capacitor used in a circuit board of a first embodiment;

FIG. 7B is a cross-sectional view taken along a line A3-A3 in FIG. 2 of a first multilayer ceramic capacitor used in a circuit board of a first embodiment;

FIG. 8A to FIG. 8C are process diagrams illustrating how solder paste is applied using a screen printing mask;

FIG. 9 is a cross-sectional view of a first multilayer ceramic capacitor used in a circuit board of a second embodiment, taken along a line segment corresponding to a line A1-A1 in FIG. 2;

FIG. 10A is a cross-sectional view of a first multilayer ceramic capacitor used in a circuit board of a second embodiment, taken along a line segment corresponding to line A2-A2 in FIG. 2;

FIG. 10B is a cross-sectional view of a first multilayer ceramic capacitor used in a circuit board of a second embodiment, taken along a line segment corresponding to line A3-A3 in FIG. 2;

FIG. 11 is a cross-sectional view of a position where a first multilayer ceramic capacitor is mounted on a circuit board of a third embodiment;

FIG. 12A is a cross-sectional view of a position where a first multilayer ceramic capacitor is mounted on a circuit board of a fourth embodiment;

FIG. 12B is a cross-sectional view of a circuit board of a fourth embodiment at a portion different in a width direction from FIG. 12A;

FIG. 13A is a cross-sectional view of a position where a first multilayer ceramic capacitor is mounted on a circuit board of a fifth embodiment;

FIG. 13B is a cross-sectional view of a circuit board of a fifth embodiment at a portion different in a width direction from FIG. 13A;

FIG. 14A is a cross-sectional view of a position where a first multilayer ceramic capacitor is mounted on a circuit board of a sixth embodiment;

FIG. 14B is a cross-sectional view of a circuit board of a sixth embodiment at a portion different in a width direction from FIG. 14A;

FIG. 15 is an oblique view of a multilayer ceramic capacitor used in a circuit board of Comparative Example;

FIG. 16A is a side view of a circuit board of Comparative Example; and

FIG. 16B is a cross-sectional view of a position where a first multilayer ceramic capacitor is mounted on a circuit board of Comparative Example.

### DETAILED DESCRIPTION

However, when the dimensions of electronic components mounted adjacent to each other on a printed wiring board are significantly different, the following inconveniences are may occur. When electronic components with significantly different dimensions are mounted on multiple lands, solder paste is printed on the lands according to the thickness of the mask. The mask used at this time may be designed so that the amount of solder paste required for the large electronic component can be supplied. However, if the mask is designed according to the amount of solder paste required for the large electronic component, excessive solder paste may be printed on the small electronic component. When excessive solder paste is supplied to the small electronic component, the solder paste may wrap around to the upper surface side of the small electronic component and a solder fillet may be formed. When a solder fillet that wraps around to the upper surface side of the electronic component is formed, vibrations caused by the bending, expansion, and contraction of the printed wiring board are transmitted to the upper surface side of the electronic component via the solder fillet, making it easier for cracks to occur in the electronic component. The solder fillet itself expands and contracts, which can affect the occurrence of cracks. If a crack occurs in an electronic component, a short circuit may occur inside the electronic component.

Below, a circuit board 100 according to an embodiment of the present invention will be described with reference to the attached drawings. In the drawings, the dimensions, ratios, or the like of each part may not be illustrated to be completely consistent with the actual ones. In addition, for convenience of drawing, some details may be omitted or components themselves may be omitted in some drawings. In addition, the drawings indicate X-axis, Y-axis, and Z-axis which are mutually orthogonal as appropriate. The X-axis, Y-axis, and Z-axis define a fixed coordinate system fixed with respect to the circuit board 100. In the following description, the Z-axis direction corresponds to the direction along the first axis, and the Y-axis direction corresponds to the direction along the second axis. The X-axis direction corresponds to the direction along the third axis.

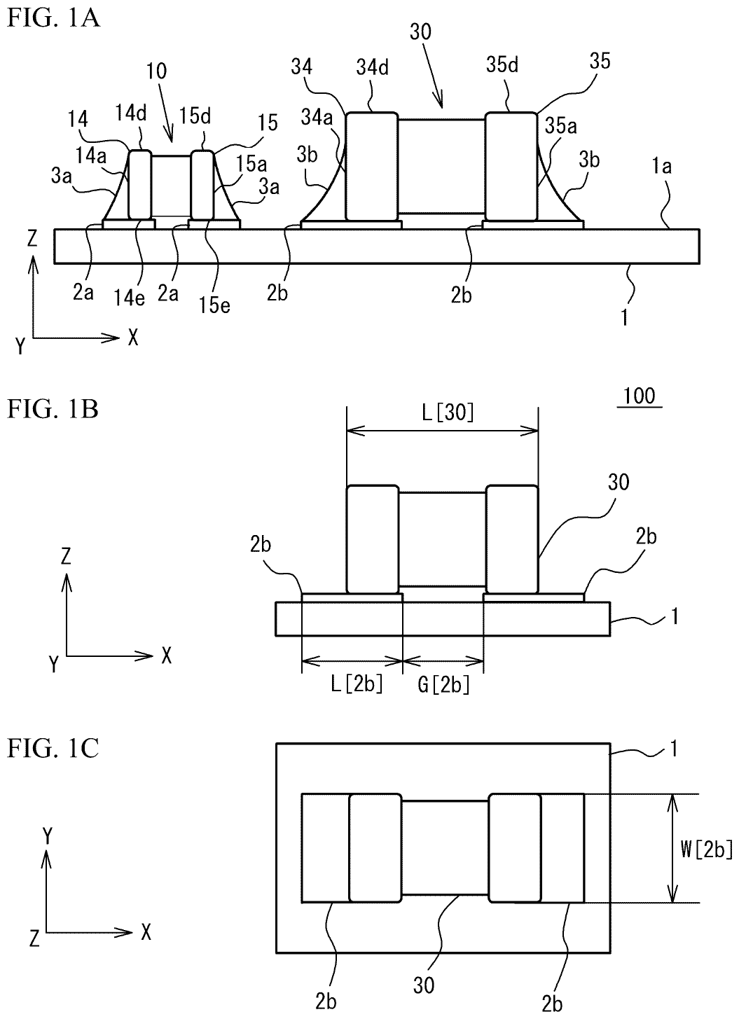

### First Embodiment

[Circuit board] First, the schematic configuration of the circuit board 100 according to the first embodiment will be described with reference to FIG. 1. FIG. 1 is a side view of the circuit board 100 according to the first embodiment. The circuit board 100 includes a printed wiring board 1 as a board, a first multilayer ceramic capacitor (MLCC: Multi Layered Ceramic Capacitor) 10, and a second multilayer ceramic capacitor 30.

The first multilayer ceramic capacitor 10 is fixed to a land 2a provided on the printed wiring board 1 by a solder fillet 3a, and is mounted on a mounting surface 1a of the printed wiring board 1.

The second multilayer ceramic capacitor 30 is fixed to a land 2b provided on the printed wiring board 1 by a solder fillet 3b, and is mounted on the mounting surface 1a of the printed wiring board 1.

Comparing the dimensions of the first multilayer ceramic capacitor 10 and the second multilayer ceramic capacitor 30, the dimensions of the second multilayer ceramic capacitor 30 are larger. Accordingly, the area of the land 2b on which the second multilayer ceramic capacitor 30 is mounted is larger than the area of the land 2a on which the first multilayer ceramic capacitor 10 is mounted. The dimensions of the first multilayer ceramic capacitor 10 and the second multilayer ceramic capacitor 30 will be described in detail later.

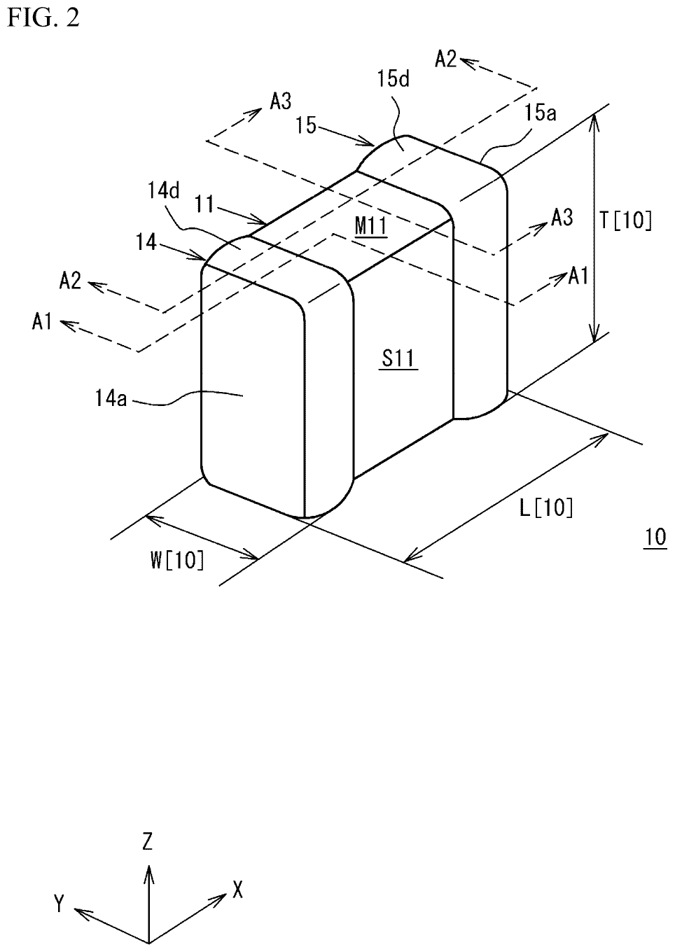

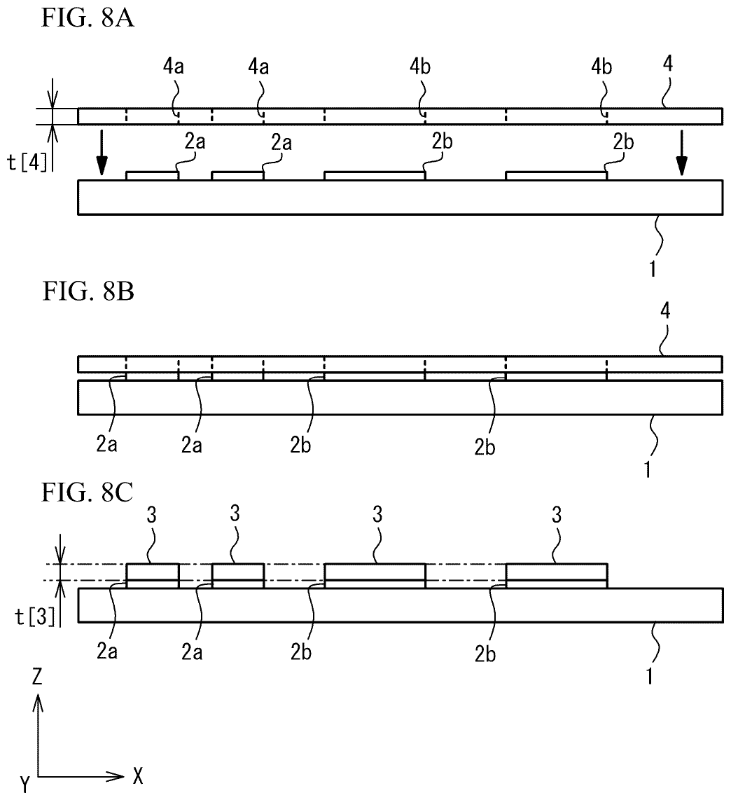

The first multilayer ceramic capacitor 10 and the second multilayer ceramic capacitor 30 are mounted on the mounting surface 1a in parallel along the X-axis direction. No other components are mounted between the first multilayer ceramic capacitor 10 and the second multilayer ceramic capacitor 30. The first multilayer ceramic capacitor 10 and the second multilayer ceramic capacitor 30 are mounted adjacent to each other. In this specification, the adjacent state refers to a state in which a solder paste 3 (see FIG. 8A to FIG. 8C) can be applied to the lands 2a and 2b using a single screen printing mask. The applied solder paste 3 forms the solder fillets 3a and 3b. The application of the solder paste 3 will be explained in detail later.

<Dimensional notation of the first multilayer ceramic capacitor and the second multilayer ceramic capacitor> Here, the notation of the dimensions of each part of the first multilayer ceramic capacitor 10 will be described with reference to FIG. 2, which is a perspective view of the first multilayer ceramic capacitor 10. The X-axis dimension of the first multilayer ceramic capacitor 10, that is, the length, is expressed as L[10], and the Y-axis dimension, that is, the width, is expressed as W[10]. The Z-axis dimension, that is, the height, is T[10].

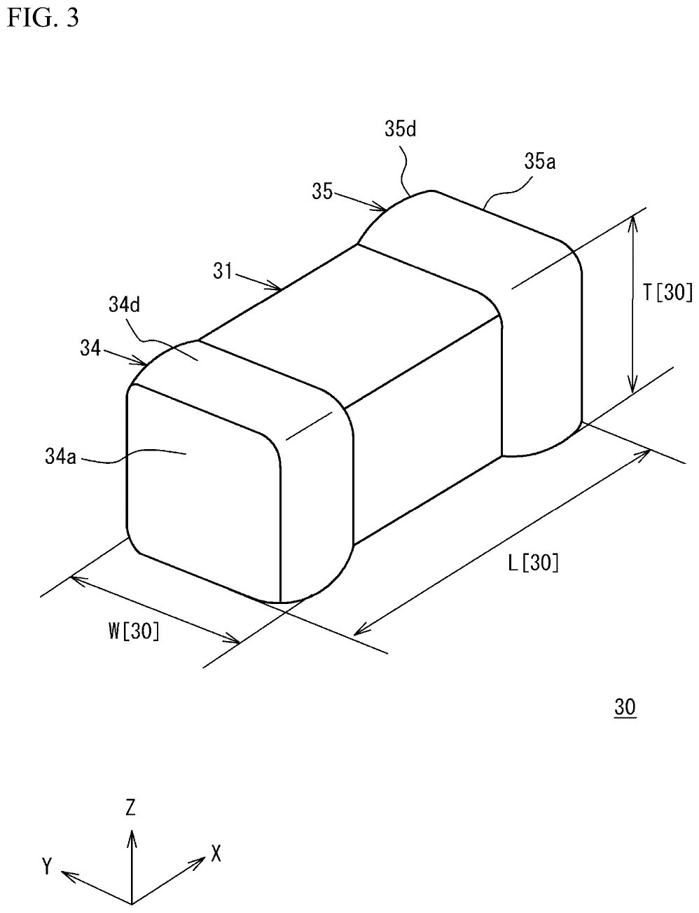

Similarly, with reference to FIG. 3, which is a perspective view of the second multilayer ceramic capacitor 30, the notation of dimensions of each portion of the second multilayer ceramic capacitor 30 will be described. The dimension in the X-axis direction of the second multilayer ceramic capacitor 30, that is, the length, is expressed as L[30], and the dimension in the Y-axis direction, that is, the width, is expressed as W[30]. The dimension in the Z-axis direction, that is, the height, is expressed as T[30].

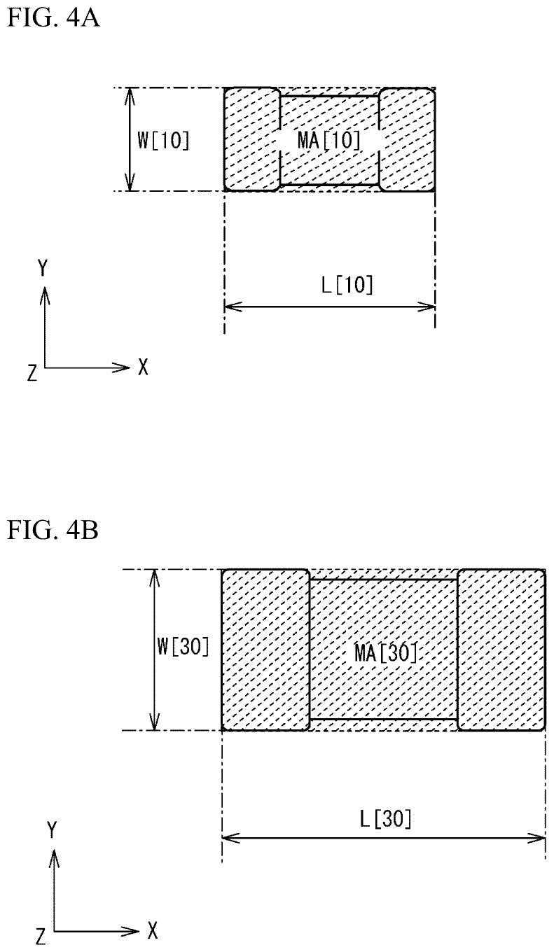

Next, referring to FIG. 4A, a mounting area MA[10] of the first multilayer ceramic capacitor 10 will be described. The mounting area MA[10] of the first multilayer ceramic capacitor 10 is the length L[10]×the width W[10]. Similarly, referring to FIG. 4B, the mounting area MA[30] of the second multilayer ceramic capacitor 30 will be described. The mounting area MA[30] of the second multilayer ceramic capacitor 30 is the length L[30]×the width W[30].

In this embodiment, the mounting area MA[10] of the first multilayer ceramic capacitor 10 is set to be 1/10 or less of the mounting area MA[30] of the second multilayer ceramic capacitor 30. The mounting area MA[10] of the first multilayer ceramic capacitor 10 may be, for example, 1/20 or less of the mounting area MA[30] of the second multilayer ceramic capacitor 30, and may be 1/30 or less of the mounting area MA[30] of the second multilayer ceramic capacitor 30. For example, when the first multilayer ceramic capacitor 10 has dimensions called 0402 shape, the mounting area MA[10] is 0.4 mm×0.2 mm, which is 0.08 mm². When the second multilayer ceramic capacitor 30 has dimensions called 2012 shape, the mounting area MA[30] is 2.0 mm×1.25 mm=2.5 mm². Therefore, in such a combination, the mounting area MA[10] of the first multilayer ceramic capacitor 10 is 32/1000 of the mounting area MA[30] of the second multilayer ceramic capacitor 30.

The ratio of the mounting areas is defined as one of the indices for indicating the state in which large and small electronic components are mounted. Therefore, if the mounting area MA[10] of the first multilayer ceramic capacitor 10 is larger than one tenth of the mounting area MA[30] of the second multilayer ceramic capacitor 30, the effect of this embodiment is not completely lost. The combination of the first multilayer ceramic capacitor 10 and the second multilayer ceramic capacitor 30 may be selected as appropriate.

The dimensions of the lands 2a and 2b will now be described. The dimensions of the lands are set as appropriate according to the dimensions of the electronic components to be mounted. FIG. 1B and FIG. 1C illustrate the dimensions of the land 2b on which the second multilayer ceramic capacitor 30 is mounted. The length L[2b] of the land 2b is set to approximately 0.35 to 0.45 times the length L[30] of the second multilayer ceramic capacitor 30 to be mounted. The distance G[2b] between the paired lands 2b is set to approximately 0.45 to 0.6 times the length L[30] of the second multilayer ceramic capacitor 30 to be mounted. The width W[2b] of the land 2b is set to approximately 1.0 to 1.15 times the width W[30] of the second multilayer ceramic capacitor 30 to be mounted. Although the land 2b on which the second multilayer ceramic capacitor 30 is mounted is illustrated in FIG. 1B and FIG. 1C, the dimensions of the land 2a on which the first multilayer ceramic capacitor 10 is mounted are set in a similar manner based on the dimensions of each part of the first multilayer ceramic capacitor 10.

<First Multilayer Ceramic Capacitor> Next, the first multilayer ceramic capacitor 10 will be described in detail.

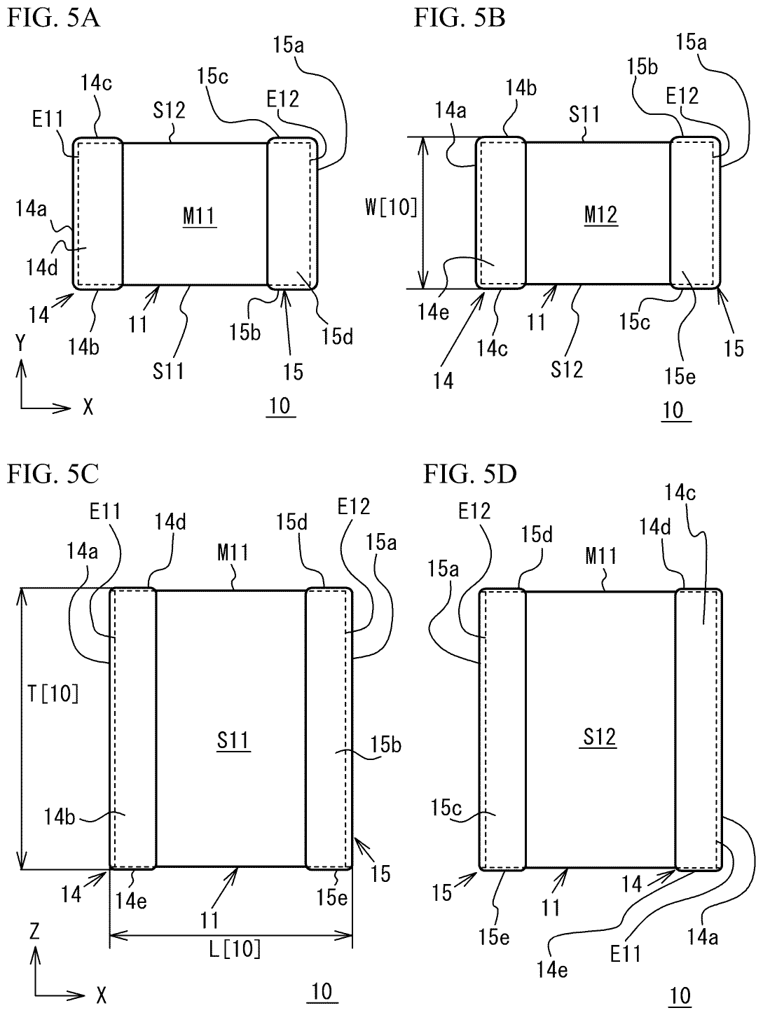

«External Shape» First, the external shape of the first multilayer ceramic capacitor 10 will be described with reference to FIG. 2, and FIG. 5A to FIG. 5B.

The first multilayer ceramic capacitor 10 includes a ceramic body 11, a first external electrode 14, and a second external electrode 15. The ceramic body 11 is configured as a hexahedron having first and second main faces M11, M12 orthogonal to the Z axis, first and second end faces E11, E12 orthogonal to the X axis, and first and second side faces S11, S12 orthogonal to the Y axis. Note that the “hexahedron” may be substantially hexahedral, and for example, the ridges connecting the faces of the ceramic body 11 may be rounded.

The main faces M11, M12, end faces E11, E12, and side faces S11, S12 of the ceramic body 11 are all configured as flat surfaces. The flat surface according to this embodiment does not have to be strictly planar as long as it is recognized as flat when viewed overall, and includes, for example, a surface having minute irregularities or a gently curved shape existing within a predetermined range.

The first multilayer ceramic capacitor 10 is a tall type having a height T[10] of 1.3 times or more the width W[10]. In the first multilayer ceramic capacitor 10, the height [T10] is increased to increase the capacity. This allows the first multilayer ceramic capacitor 10 to be mounted in a mounting space that is limited in the Y-axis direction. It is desirable to set the height T[10] to 1.5 times or more the width W[10]. The height T[10] can be set to, for example, 1.6 times or 1.7 times the width W[10], or even higher. This allows the first multilayer ceramic capacitor 10 to have a larger capacity.

The relationship between the height T[10] and width W[10] in the first multilayer ceramic capacitor 10 affects the shape of the solder fillet 3a (see FIG. 1). The shape of the solder fillet 3a will be described in detail later.

In the first multilayer ceramic capacitor 10, the dimension of the ceramic body 11 in the X-axis direction may be larger than the dimension in the Y-axis direction, and may be smaller than the dimension in the Z-axis direction. In the first multilayer ceramic capacitor 10, the dimensions of the ceramic body 11 in the three axial directions can be determined arbitrarily within the range that satisfies the above conditions.

In the first multilayer ceramic capacitor 10 of this embodiment, for example, the length L[10] may be set to 0.2 mm or more and 1.2 mm or less, and the width W[10] may be set to 0.1 mm or more and 0.7 mm or less. Also, the height T[10] may be set to 0.15 mm or more and 1.0 mm or less. The height T[10], the width W[10], and the length L[10] are all maximum dimensions of the first multilayer ceramic capacitor 10 in each direction.

The first external electrode 14 has a first surface portion 14a that covers the end face E11 of the ceramic body 11. The first external electrode 14 has a second surface portion 14b extending from the first surface portion 14a to the side face S11, and a third surface portion 14c extending to the side face S12. Furthermore, the first external electrode 14 has a fourth surface portion 14d extending from the first surface portion 14a to the main face M11, and a fifth surface portion 14e extending to the main face M12.

The second external electrode 15 has a first surface portion 15a covering the end face E12 of the ceramic body 11. The second external electrode 15 has a second surface portion 15b extending from the first surface portion 15a to the side face S11, and a third surface portion 15c extending to the side face S12. Furthermore, the second external electrode 15 has a fourth surface portion 15d extending from the first surface portion 15a to the main face M11, and a fifth surface portion 15e extending to the main face M12.

Here, the second surface portions 14b and 15b, the third surface portions 14c and 15c, the fourth surface portions 14d and 15d, and the fifth surface portions 14e and 15e correspond to extension portions.

The external electrodes 14 and 15 have U-shaped cross sections parallel to the X-Z plane and the X-Y plane. The shape of the external electrodes 14 and 15 is not limited to the example illustrated in the drawings.

The external electrodes 14 and 15 contain a metal material as a main component. An example of the metal material constituting the external electrodes 14 and 15 is such as copper (Cu), nickel (Ni), tin (Sn), palladium (Pd), platinum (Pt), silver (Ag), gold (Au), or alloys of these. In this embodiment, the main component refers to the component with the highest content.

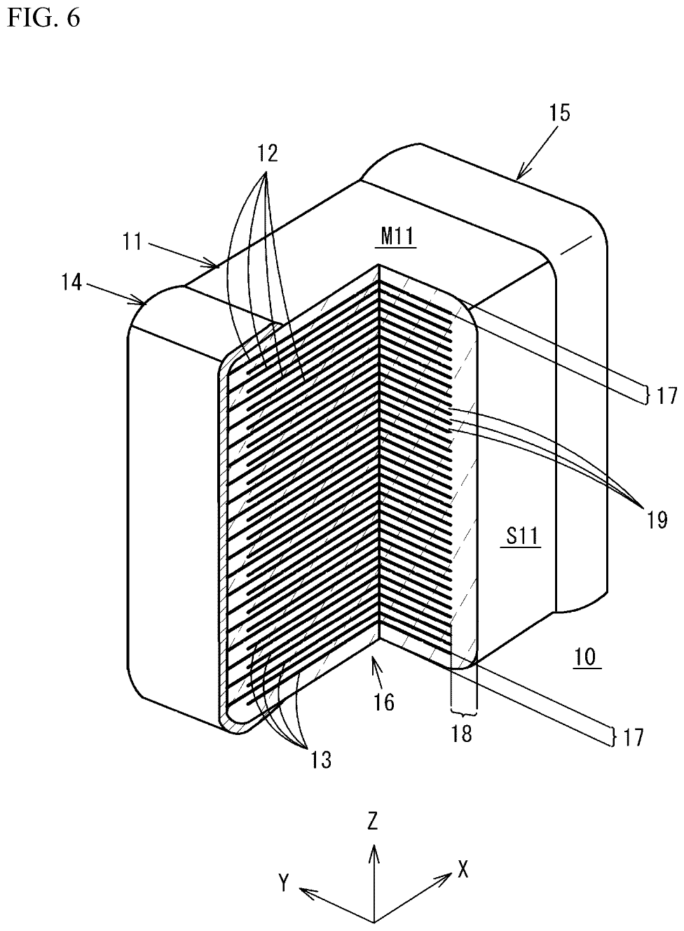

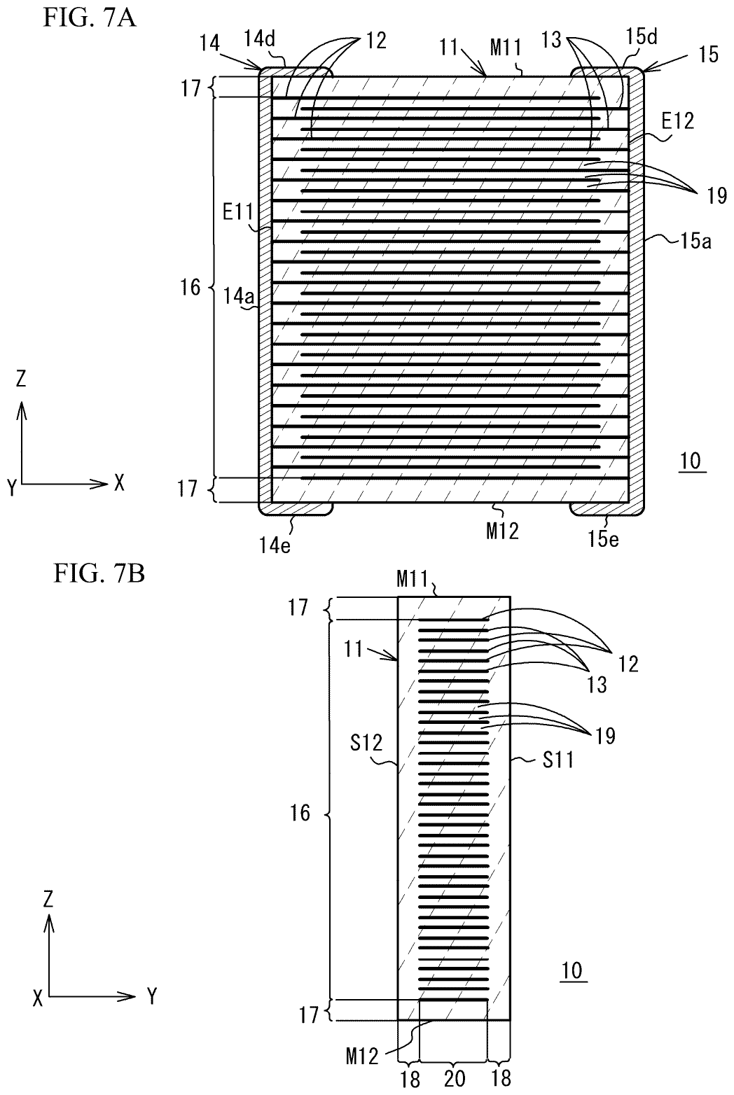

«Internal Structure» Next, the internal structure of the first multilayer ceramic capacitor 10 will be described with reference to FIG. 6 to FIG. 7B. FIG. 6 is a cross-sectional view of the first multilayer ceramic capacitor 10 taken along a line A1-A1 in FIG. 2. FIG. 7A is a cross-sectional view of the first multilayer ceramic capacitor 10 taken along a line A2-A2 in FIG. 2. FIG. 7B is a cross-sectional view of the first multilayer ceramic capacitor 10 taken along a line A3-A3 in FIG. 2. In FIG. 7B, the second external electrode 15 is omitted.

The ceramic body 11 has a multilayer portion 20 and a pair of margin portions 18. The multilayer portion 20 has a capacity forming portion 16 and a pair of cover portions 17. The capacity forming portion 16 includes a plurality of first and second internal electrodes 12, 13 alternately stacked with a plurality of ceramic layers 19 along the Z-axis direction. In this embodiment, the first internal electrode 12, the second internal electrode 13, and the ceramic layers 19 are each configured in a sheet shape extending along the X-Y plane. In addition, the number of layers of the first and second internal electrodes 12, 13 in each figure does not represent the actual number of layers.

The first and second internal electrodes 12, 13 are alternately arranged along the Z-axis direction so as to face each other in the Z-axis direction. The first and second internal electrodes 12, 13 face each other in the Z-axis direction in a facing section in the center of the X-axis and Y-axis directions. The first internal electrodes 12 corresponds to the first group, are drawn out from the facing section to one end face E11, and are connected to the first external electrode 14. The second internal electrodes 13 corresponds to the second group, are drawn out from the facing section to the other end face E12, and are connected to the second external electrode 15.

The first and second internal electrodes 12, 13 contain a metal material as a main component. The metal material is typically nickel (Ni), but other example is such as copper (Cu), palladium (Pd), platinum (Pt), silver (Ag), gold (Au), or alloys thereof.

With this configuration, when a voltage is applied between the external electrodes 14, 15 in the first multilayer ceramic capacitor 10, the voltage is applied to the plurality of ceramic layers 19 between the internal electrodes 12, 13 in the facing section. As a result, a charge corresponding to the voltage between the external electrodes 14, 15 is stored in the first multilayer ceramic capacitor 10.

In order to increase the electrostatic capacity of each of the ceramic layers 19 between the first and second internal electrodes 12, 13 in the multilayer portion 20, a dielectric ceramic with a high dielectric constant is used. An example of dielectric ceramics with a high dielectric constant is such as perovskite-structured materials containing barium (Ba) and titanium (Ti), such as barium titanate (BaTiO₃).

The dielectric ceramic may be a composition system such as strontium titanate (SrTO₃), calcium titanate (CaTiO₃), magnesium titanate (MgTiO₃), calcium zirconate (CaZrO₃), calcium zirconate titanate (Ca(Zr,Ti)O₃), barium calcium zirconate titanate ((Ba,Ca)(Zr,Ti)O₃), barium zirconate (BaZrO₃), titanium oxide (TiO₂) or the like.

The pair of cover portions 17 cover the capacity forming portion 16 from both sides in the Z-axis direction, which is the stacking direction. The cover portion 17 is sometimes referred to as a protective layer in the height direction. The cover portion 17 is composed, for example, of a multilayer structure of ceramic sheets extending along the XY plane. From the standpoint of suppressing internal stress, it is preferable that the dielectric ceramic that composes the cover portion 17 has the same composition as the ceramic layer 19.

The pair of margin portions 18 are formed along the Z-axis direction and cover the multilayer portion 20 from the Y-axis direction. The margin portions 18 are sometimes called width-direction protective layers. The margin portions 18 are attached to the surfaces of the multilayer portion 20 orthogonal to the Y-axis. For example, the margin portions 18 are formed of ceramic sheets and configured in a sheet shape extending along the X-Z plane. From the viewpoint of suppressing internal stress or the like, it is preferable that the dielectric ceramics constituting the margin portions 18 have the same composition as the ceramic layer 19. For example, the margin portion 18 may be formed by stacking a plurality of ceramic sheets on which internal electrode formation layers are provided, leaving portions corresponding to the margin portion.

<Second multilayer ceramic capacitor> Next, the second multilayer ceramic capacitor 30 will be described. As described above, the second multilayer ceramic capacitor 30 corresponds to another electronic component, but the electronic component does not necessarily have to be a multilayer ceramic capacitor. The electronic component may be any conventional electronic component that is mounted on the printed wiring board 1 and satisfies the positional relationship with the first multilayer ceramic capacitor 10 and the mounting area relationship.

«External shape» The second multilayer ceramic capacitor 30 includes a ceramic body 31, a first external electrode 34, and a second external electrode 35, similar to the first multilayer ceramic capacitor 10. The first external electrode 34 has a configuration in common with the first external electrode 14 in the first multilayer ceramic capacitor 10, such as a first surface portion 34a and a fourth surface portion 34d. The second external electrode 35 has a structure common to the second external electrode 15 of the first multilayer ceramic capacitor 10, such as a first surface portion 35a and a fourth surface portion 35d. As described above, the second multilayer ceramic capacitor 30 is merely one example of another electronic component, and does not necessarily have to have the above-mentioned external shape. The second multilayer ceramic capacitor 30 only needs to have a form that allows the second multilayer ceramic capacitor 30 to be mounted on the land 2b illustrated in FIG. 1 at the very least. In addition, the second multilayer ceramic capacitor 30 may adopt various conventionally known forms for its internal structure, for example, the arrangement of the internal electrodes. Therefore, a detailed description of the internal structure of the second multilayer ceramic capacitor 30 will be omitted here.

<Solder fillet> Returning to FIG. 1, the first external electrode 14 and the second external electrode 15 of the first multilayer ceramic capacitor 10 are fixed to the land 2a by the solder fillet 3a.

First, the first external electrode 14 will be described. The first external electrode 14 is connected to the land 2a with the fifth surface portion 14e in contact with the land 2a. The solder fillet 3a is formed so as to be in contact with a part of the land 2a and the first surface portion 14a of the first external electrode 14. That is, the solder fillet 3a does not reach the fourth surface portion 14d. The same is true for the second external electrode 15, which is connected to the land 2a with the fifth surface portion 15e in contact with the land 2a. The solder fillet 3a is formed so as to be in contact with a part of the land 2a and the first surface portion 15a of the second external electrode 15. That is, the solder fillet 3a does not reach the fourth surface 15d. The reason why the solder fillet 3a does not reach the fourth surface portions 14d and 15d is because the first multilayer ceramic capacitor 10 is a high-profile type in which the height T[10] is 1.3 times or more the width W[10].

Now, referring to FIG. 8A to FIG. 8C, the application of the solder paste 3 that forms the solder fillets 3a, 3b will be described. The solder paste 3 is formed using a screen printing mask 4. As illustrated in FIG. 8A, the mask 4 has through holes 4a, 4b that are formed to correspond to the lands 2a, 2b provided on the printed wiring board 1. The mask 4 has a thickness of t[4], and the through holes 4a, 4b have a depth corresponding to this. As illustrated in FIG. 8B, the solder paste 3 is applied with the mask 4 placed on the printed wiring board 1. Then, when the mask 4 is removed, the solder paste 3 is formed on the lands 2a, 2b as illustrated in FIG. 8C. The solder paste 3 formed on the land 2a and the solder paste 3 formed on the land 2b both have the same thickness, t[3].

When mounting the first multilayer ceramic capacitor 10 on the printed wiring board 1, if the height of the first multilayer ceramic capacitor 10 is low, there is a possibility that the solder fillet 3a will reach and wrap around the fourth surface portions 14d and 15d. This is because the thickness t[3] of the solder paste 3 is set so that the amount of solder paste can reliably fix the second multilayer ceramic capacitor 30, which has a large mounting area. As mentioned above, the dimensions of the land are usually set according to the dimensions of the electronic component to be mounted. Therefore, the area of the land 2a is smaller than the area of the land 2b. Despite this, the thicknesses of the solder paste 3 formed on the land 2a and the solder paste 3 formed on the land 2b are both thickness t[3]. Therefore, if the thickness t[3] of the solder paste 3 is set to match the dimensions of the second multilayer ceramic capacitor 30, the amount of the solder paste 3 will be excessive for the first multilayer ceramic capacitor 10, which has a small dimension.

If the solder fillet 3a reaches the fourth surface portions 14d, 15d, cracks are more likely to occur near the boundary between the fourth surface portions 14d, 15d and the ceramic body 11 (see FIG. 1 and FIG. 2). This is thought to be because when the solder fillet 3a reaches the fourth surface portions 14d, 15d and wraps around and covers the fourth surface portions 14d, 15d, stress concentration increases near the boundary between the fourth surface portions 14d, 15d and the ceramic body 11.

In addition, the solder fillet 3a is thought to propagate stress generated in the printed wiring board 1. Therefore, when the solder fillet 3a covers the fourth surface portions 14d, 15d, the stress generated by the expansion, contraction, and bending of the printed wiring board 1 is propagated to the vicinity of the boundary between the fourth surface portions 14d, 15d and the ceramic body 11. As a result, it is thought that the occurrence of cracks is induced and the cracks expand.

According to the first multilayer ceramic capacitor 10 of this embodiment, the solder fillet 3a does not reach the fourth surface portions 14d, 15d. This suppresses the increase in stress concentration near the boundary between the fourth surface portions 14d, 15d and the ceramic body 11. In addition, the stress generated in the printed wiring board 1 is suppressed from propagating to the vicinity of the boundary between the fourth surface portions 14d, 15d and the ceramic body 11. As a result, the occurrence and expansion of cracks near the boundary between the fourth surface portions 14d, 15d and the ceramic body 11 is suppressed.

If a crack occurs near the boundary between the fourth surface portions 14d, 15d and the ceramic body 11, the crack can expand within the ceramic body 11. If the expanded crack reaches the internal electrode 12 or the internal electrode 13, a short circuit may occur. If solder or conductive dust, for example, gets into the crack that has reached the internal electrode 12 or the internal electrode 13, a short circuit may easily occur. Furthermore, if moisture or the like gets into the crack, the crack may easily expand further. In this embodiment, the occurrence of such cracks is suppressed. As a result, the occurrence of a short circuit is also suppressed.

Note that the same effect may be obtained when the first multilayer ceramic capacitor 10 is inverted and mounted with the fourth surface portions 14d, 15d placed on the lands 2a.

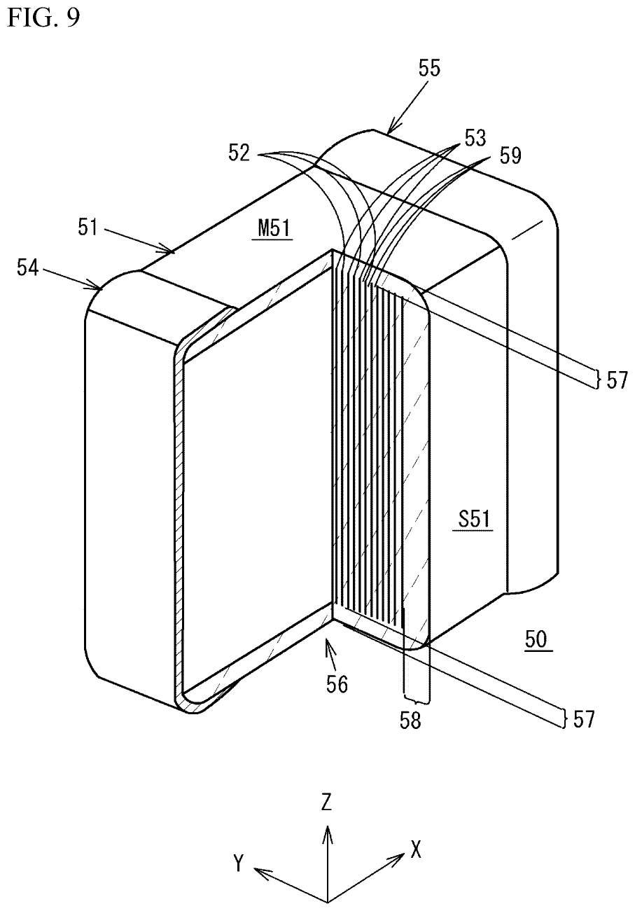

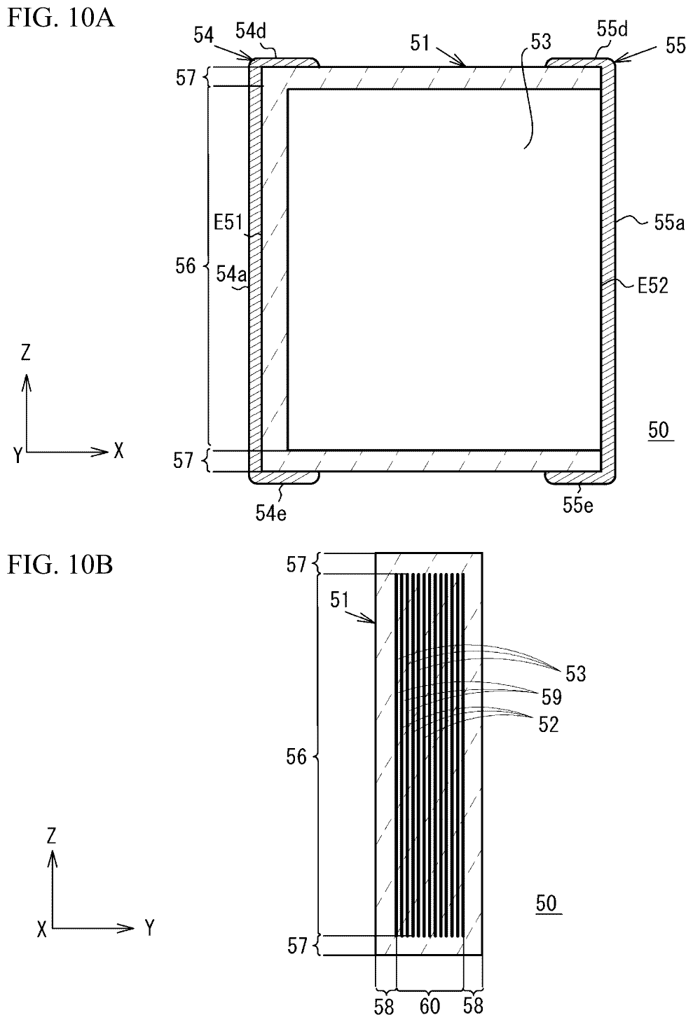

(Second embodiment) Next, the second embodiment will be described. In the second embodiment, a first multilayer ceramic capacitor 50 illustrated in FIG. 9 to FIG. 10B is mounted on the printed wiring board 1 instead of the first multilayer ceramic capacitor 10 illustrated in FIG. 1.

«External Shape» The external shape of the first multilayer ceramic capacitor 50 is generally the same as that of the first multilayer ceramic capacitor 10 of the first embodiment. That is, the first multilayer ceramic capacitor 50 includes a ceramic body 51, a first external electrode 54, and a second external electrode 55. The first external electrode 54 includes a first surface portion 54a, a second surface portion (not illustrated), a third surface portion (not illustrated), a fourth surface portion 54d, and a fifth surface portion 54e. The second external electrode 55 has a first surface portion 55a, a second surface portion (not illustrated), a third surface portion (not illustrated), a fourth surface portion 55d, and a fifth surface portion 55e. The first multilayer ceramic capacitor 50 has a first main face M51, a first side face S51, and the like. These components are common to the corresponding parts of the first multilayer ceramic capacitor 10 of the first embodiment, so detailed description thereof will be omitted here.

The length, the width, and the height of the first multilayer ceramic capacitor 50 are not illustrated, but are represented as the length L[50], width W[50], and height T[50], respectively, as in the first multilayer ceramic capacitor 10 of the first embodiment. The first multilayer ceramic capacitor 50 is a high-profile type in which the height T[50] is 1.3 times or more larger than the width W[50]. This point is also similar to the first multilayer ceramic capacitor 10 of the first embodiment.

«Internal Structure» Next, the internal structure of the first multilayer ceramic capacitor 50 in the second embodiment will be described with reference to FIG. 9 to FIG. 10B. FIG. 9 is a cross-sectional view of the first multilayer ceramic capacitor 50 taken along a line corresponding to the A1-A1 line in FIG. 2. In other words, it is a cross-sectional view corresponding to the A1-A1 line of the first multilayer ceramic capacitor 10 in the first embodiment. FIG. 10A is a cross-sectional view of the first multilayer ceramic capacitor 50 taken along a line corresponding to the A2-A2 line in FIG. 2. In other words, it is a cross-sectional view corresponding to the A2-A2 line cross-sectional view of the first multilayer ceramic capacitor 10 in the first embodiment. FIG. 10B is a cross-sectional view of the first multilayer ceramic capacitor 50 taken along a line corresponding to the A3-A3 line in FIG. 2. In other words, it is a cross-sectional view corresponding to the A3-A3 line cross-sectional view of the first multilayer ceramic capacitor 10 in the first embodiment. Note that the second external electrode 55 is omitted in FIG. 10B.

The ceramic body 51 has a multilayer portion 56 and a pair of cover portions 57. The multilayer portion 56 has a capacity forming portion 60 and a pair of margin portions 58. The capacity forming portion 60 includes a plurality of first and second internal electrodes 52, 53 that are alternately stacked with a plurality of ceramic layers 59 along the Y-axis direction. In this embodiment, the internal electrodes 52, 53 and the ceramic layers 59 are each configured in a sheet shape extending along the X-Z plane. The internal electrodes 52, 53 are stacked along the Y-axis direction and face each other in a direction parallel to the mounting surface 1a, so that the bonding area between each of the first internal electrodes 52 and the first external electrode 54 and the bonding area between each of the second internal electrodes 53 and the second external electrode 55 can be made large. This suppresses the capacity reduction due to poor contact, so-called capacity loss. Note that the number of layers of the first and second internal electrodes 52, 53 in each figure does not represent the actual number of layers.

The internal electrodes 52, 53 are alternately arranged along the Y-axis direction so as to face each other in the Y-axis direction. The internal electrodes 52, 53 face each other in the Y-axis direction in the central facing section in the X-axis direction and the Z-axis direction. The first internal electrodes 52 correspond to the first group, are drawn from the facing section to one end face E51, and are connected to the first external electrode 54. The second internal electrodes 53 correspond to the second group, are drawn from the facing section to the other end face E52, and are connected to the second external electrode 55.

The internal electrodes 52, 53 contain a metal material as a main component. A typical example of the metal material is such as nickel (Ni), and other example is such as copper (Cu), palladium (Pd), platinum (Pt), silver (Ag), gold (Au), or alloys thereof.

With this configuration, when a voltage is applied between the external electrodes 54, 55 in the first multilayer ceramic capacitor 50, the voltage is applied to the multiple ceramic layers 59 between the internal electrodes 52, 53 in the facing section. As a result, in the second multilayer ceramic capacitor 30, a charge corresponding to the voltage between the external electrodes 54, 55 is stored.

In the multilayer portion 56, a dielectric ceramic with a high dielectric constant is used to increase the electrostatic capacity of each of the ceramic layers 59 between the internal electrodes 52, 53. An example of dielectric ceramics with a high dielectric constant is such as perovskite-structured materials containing barium (Ba) and titanium (Ti), such as barium titanate (BaTiO₃).

The dielectric ceramic may be a composition system such as strontium titanate (SrTiO₃), calcium titanate (CaTiO₃), magnesium titanate (MgTiO₃), calcium zirconate (CaZrO₃), calcium zirconate titanate (Ca(Zr,Ti)O₃), barium calcium zirconate titanate ((Ba,Ca)(Zr,Ti)O₃), barium zirconate (BaZrO₃), titanium oxide (TiO₂), or the like.

The pair of cover portions 57 are formed along the Y-axis direction and cover the multilayer portion 56 from the Z-axis direction. The cover portion 57 may also be referred to as a protective layer in the height direction. The cover portion 57 is attached later to a surface of the multilayer portion 56 orthogonal to the Z-axis. The cover portion 57 is formed, for example, by a multilayer structure of ceramic sheets extending along the X-Y plane. The dielectric ceramics constituting the cover portion 57 preferably have the same composition as the ceramic layer 59 from the viewpoint of suppressing internal stress. The forming method of the cover portion 57 is not limited to this. For example, the cover portion 57 may be formed by stacking ceramic sheets on which the internal electrode formation layer is provided, leaving the portion corresponding to the cover portion.

The pair of margin portions 58 are formed along the Z-axis direction and cover the capacity forming portion 60 from the Y-axis direction. The margin portions 58 are sometimes called widthwise protective layers. The margin portions 58 are formed, for example, by ceramic sheets and are configured in a sheet shape extending along the X-Z plane. The dielectric ceramics constituting the margin portions 58 preferably have the same composition as the ceramic layer 59 from the viewpoint of suppressing internal stress.

The first multilayer ceramic capacitor 50 is mounted on the printed wiring board 1 in the same manner as the first multilayer ceramic capacitor 10 of the first embodiment illustrated in FIG. 1. At this time, the solder fillet 3a does not reach the fourth surface portions 54d, 55d. This is because the first multilayer ceramic capacitor 50 is a high-profile type in which the height T[50] is 1.3 times or more the width W[50].

Similar to the first multilayer ceramic capacitor 10, the first multilayer ceramic capacitor 50 is suppressed from causing and expanding cracks near the boundaries between the fourth surface portions 54d, 55d and the ceramic body 51. Also, the occurrence of short circuits within the ceramic body 51 is prevented.

Note that electrostriction may occur in the first multilayer ceramic capacitor 50. The electrostriction may cause so-called acoustic noise. However, the stacking direction of the internal electrodes 52, 53 in the first multilayer ceramic capacitor 50 is along the Y-axis, which is the mounting direction, that is, orthogonal to the Z-axis direction. As a result, acoustic noise is suppressed in the first multilayer ceramic capacitor 50.

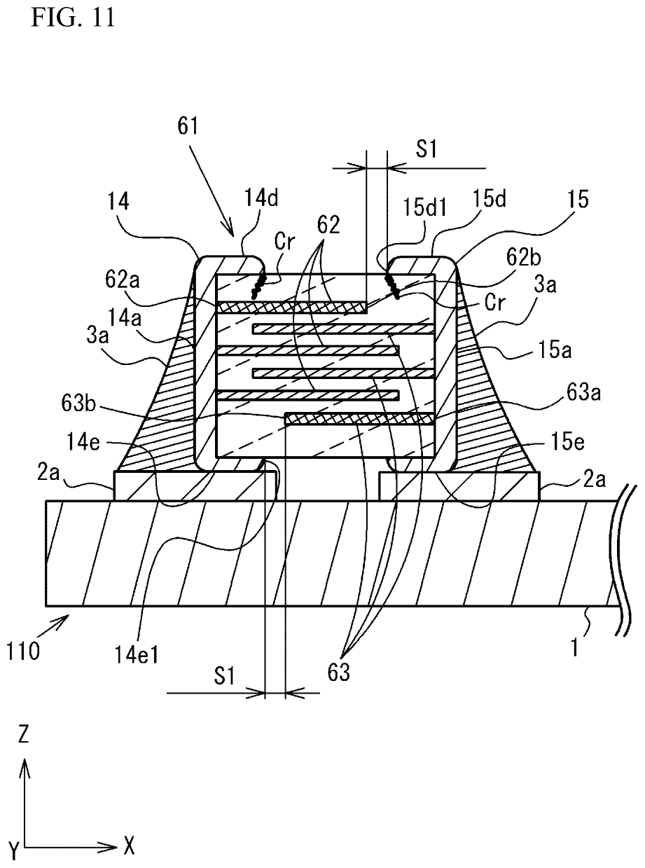

(Third embodiment) Next, the third embodiment will be described. In the third embodiment, instead of the first multilayer ceramic capacitor 10 illustrated in FIG. 1, a first multilayer ceramic capacitor 61 illustrated in FIG. 11 is mounted on the printed wiring board 1. FIG. 11 is a cross-sectional view of a circuit board 110 of the third embodiment at the position where the first multilayer ceramic capacitor 61 is mounted. The cross-section illustrated in FIG. 11 is simplified compared to FIG. 7A in order to easily illustrate the characteristic parts of the first multilayer ceramic capacitor 61.

«External shape» The external shape of the first multilayer ceramic capacitor 61 is generally the same as that of the first multilayer ceramic capacitor 10 of the first embodiment. Among the components of the first multilayer ceramic capacitor 61, the components that are common to the first multilayer ceramic capacitor 10 of the first embodiment are given the same reference numbers in the drawings, and detailed description thereof will be omitted.

«Internal Structure» The first multilayer ceramic capacitor 61 has internal electrodes 62, 63 instead of the internal electrodes 12, 13 of the first multilayer ceramic capacitor 10 of the first embodiment. In FIG. 11, of the multiple internal electrodes 62 connected to the first external electrode 14, the internal electrode 62 farthest from the printed wiring board 1 is illustrated with hatching different from that of the other internal electrodes 62. This internal electrode 62 farthest from the printed wiring board 1 has a connection end 62a connected to the first external electrode 14 and an open end 62b located on the opposite side to the connection end 62a. This open end 62b is located closer to the first external electrode 14 than an edge 15d1 of the fourth surface portion 15d extended from the second external electrode 15. In other words, a gap S1 is provided between the open end 62b and the edge 15d1.

The first multilayer ceramic capacitor 61 has a structure that suppresses the occurrence of cracks Cr. However, depending on the environment in which the first multilayer ceramic capacitor 61 is used, the crack Cr may occur near the edge 15d1 of the fourth surface portion 15d included in the second external electrode 15, as illustrated in FIG. 11. If the crack Cr reaches the internal electrode 62, a short circuit may occur between the internal electrode 62 and the second external electrode 15.

In this embodiment, the occurrence of such a short circuit is suppressed by providing the gap S1. Note that there may be the multiple internal electrodes 62 with the gap S1 provided.

The internal electrode 63 closest to the printed wiring board 1 also has the gap S1 between an open end 63b located on the opposite side of a connection end 63a and an edge 14e1 of the fifth surface portion 14e extended from the first external electrode 14. This makes it possible to suppress the occurrence of a short circuit when the first multilayer ceramic capacitor 61 is mounted on the printed wiring board 1 in an inverted state. The internal electrodes 63 with the gap S1 may also be multiple.

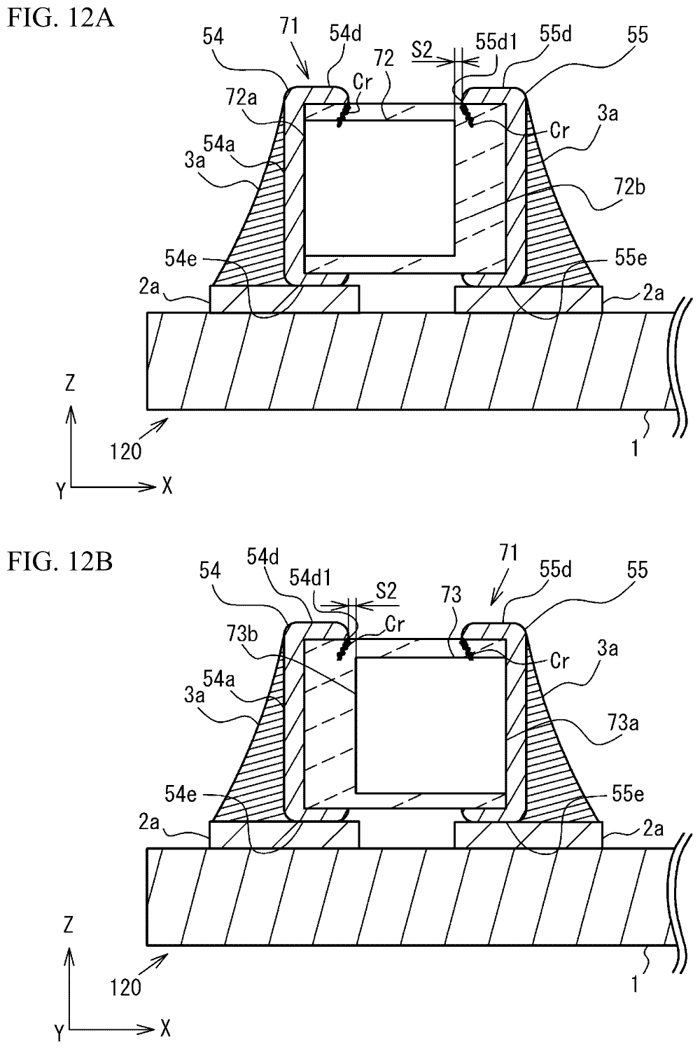

(Fourth embodiment) Next, the fourth embodiment will be described. In the fourth embodiment, instead of the first multilayer ceramic capacitor 10 illustrated in FIG. 1, a first multilayer ceramic capacitor 71 illustrated in FIG. 12A and FIG. 12B is mounted on the printed wiring board 1. Internal electrodes 72, 73 in the first multilayer ceramic capacitor 71 of the fourth embodiment are alternately arranged along the Y-axis direction so as to face each other in the Y-axis direction, similar to the first multilayer ceramic capacitor 50 of the second embodiment. FIG. 12A is a cross-sectional view of a circuit board 120 of the fourth embodiment at a position where the first multilayer ceramic capacitor 71 is mounted, and illustrates the state where the internal electrode 72 is exposed. FIG. 12B is a cross-sectional view of the circuit board 120 of the fourth embodiment at a portion different in the width direction from FIG. 12A, and illustrates the state where the internal electrode 73 is exposed.

«External Shape» The external shape of the first multilayer ceramic capacitor 71 is generally the same as that of the first multilayer ceramic capacitor 50 of the second embodiment. Among the components of the first multilayer ceramic capacitor 71, the components common to the first multilayer ceramic capacitor 50 of the second embodiment are given the same reference numbers in the drawings, and detailed description thereof is omitted.

«Internal Structure» The first multilayer ceramic capacitor 71 has the internal electrodes 72 and 73 instead of the internal electrodes 52 and 53 of the first multilayer ceramic capacitor 50 of the second embodiment.

The internal electrodes 72 correspond to the first group, and each of the internal electrodes 72 has a connection end 72a connected to the first external electrode 54, and an open end 72b located opposite the connection end 72a, as illustrated in FIG. 12A. Here, the open end means the end that is not connected to the other external electrode. This open end 72b is located closer to the first external electrode 54 than an edge 55d1 of the fourth surface portion 55d extended from the second external electrode 55. In other words, a gap S2 is provided between the open end 72b and the edge 55d1.

The internal electrodes 73 correspond to the second group, and each of the internal electrodes 73 has a connection end 73a connected to the second external electrode 55, and an open end 73b located opposite the connection end 73a, as illustrated in FIG. 12B. The open end here is as described above. The open end 73b is located closer to the second external electrode 55 than an edge 54d1 of the fourth surface portion 54d extended from the first external electrode 54. In other words, the gap S2 is provided between the open end 73b and the edge 54d1.

The first multilayer ceramic capacitor 71 has a structure that suppresses the occurrence of the cracks Cr. However, depending on the usage environment of the first multilayer ceramic capacitor 71, the cracks Cr may occur near the edge 55d1 of the fourth surface portion 55d included in the second external electrode 55, as illustrated in FIG. 12A. If this crack Cr reaches the internal electrode 72, there is a possibility that a short circuit occurs between the internal electrode 72 and the second external electrode 55.

In this embodiment, the occurrence of such a short-circuit is suppressed by providing the gap S2 between the open end 72b and the edge 55d1.

Similarly, depending on the usage environment of the first multilayer ceramic capacitor 71, the crack Cr may occur near the edge 54d1 of the fourth surface portion 54d included in the first external electrode 54, as illustrated in FIG. 12B. If this crack Cr reaches the internal electrode 73, there is a possibility that a short circuit occurs between the internal electrode 73 and the first external electrode 54.

However, in this embodiment, the occurrence of such a short-circuit is suppressed by providing the gap S2 between the open end 73b and the edge 54d1.

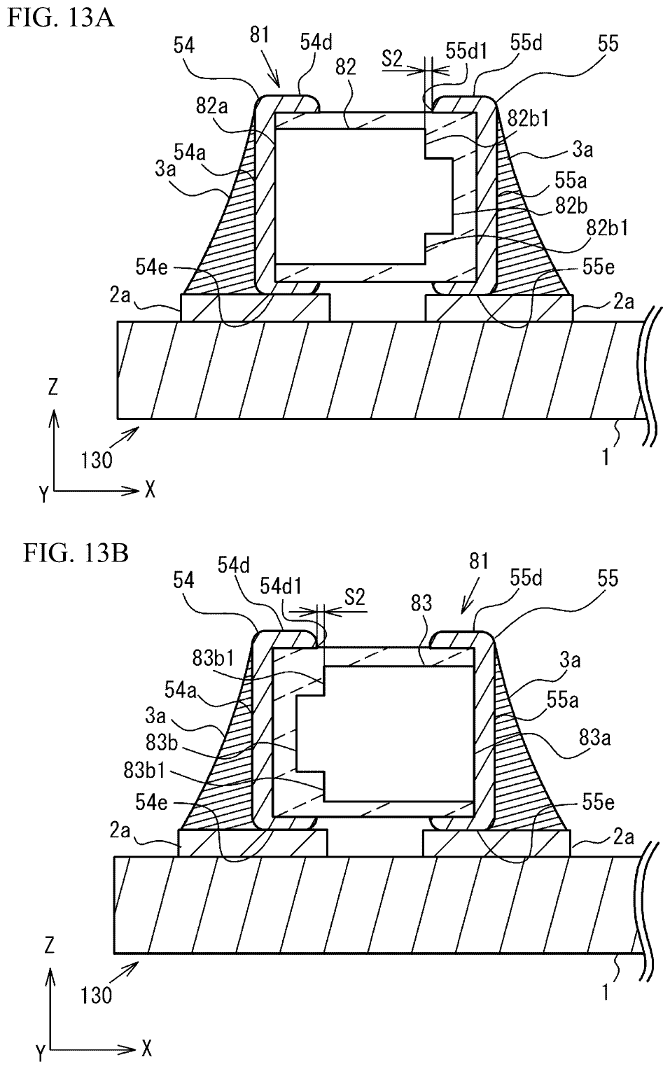

(Fifth embodiment) Next, the fifth embodiment will be described. In the fifth embodiment, instead of the first multilayer ceramic capacitor 10 illustrated in FIG. 1, a first multilayer ceramic capacitor 81 illustrated in FIG. 13A and FIG. 13B is mounted on the printed wiring board 1. Internal electrodes 82, 83 in the first multilayer ceramic capacitor 81 of the fifth embodiment are alternately arranged along the Y-axis direction so as to face each other in the Y-axis direction, similar to the first multilayer ceramic capacitor 50 of the second embodiment. FIG. 13A is a cross-sectional view of the position where the first multilayer ceramic capacitor 81 of a circuit board 130 of the fifth embodiment is mounted, and illustrates a state in which the internal electrode 82 is exposed. FIG. 13B is a cross-sectional view of a portion of the circuit board 130 of the fifth embodiment that is different in the width direction from FIG. 13A, and illustrates a state in which the internal electrode 83 is exposed.

«External Shape» The external shape of the first multilayer ceramic capacitor 81 is generally the same as that of the first multilayer ceramic capacitor 50 of the second embodiment. Among the components of the first multilayer ceramic capacitor 81, those components common to the first multilayer ceramic capacitor 50 of the second embodiment are given the same reference numbers in the drawings, and detailed descriptions thereof are omitted.

<Internal Structure> The first multilayer ceramic capacitor 81 has the internal electrodes 82, 83 instead of the internal electrodes 52, 53 of the first multilayer ceramic capacitor 50 of the second embodiment.

The internal electrodes 82 correspond to the first group, and each of the internal electrodes 82 has a connection end 82a connected to the first external electrode 54 and an open end 82b located on the opposite side to the connection end 82a, as illustrated in FIG. 13A. This open end 82b has a notch 82b1 at the edge farthest from the printed wiring board 1 when the first multilayer ceramic capacitor 81 is mounted on the printed wiring board 1. The notch 82b1 is recessed from the edge toward the printed wiring board 1. This forms the gap S2.

The internal electrodes 83 correspond to the second group, and each of the internal electrodes 83 has a connection end 83a connected to the second external electrode 55, and an open end 83b located opposite the connection end 83a, as illustrated in FIG. 13B. This open end 83b has a notch 83b1 at the edge farthest from the printed wiring board 1 when the first multilayer ceramic capacitor 81 is mounted on the printed wiring board 1. The notch 83b1 is recessed from the edge toward the printed wiring board 1. This forms the gap S2.

The first multilayer ceramic capacitor 81 has a structure that suppresses the occurrence of the cracks Cr. However, depending on the environment in which the first multilayer ceramic capacitor 81 is used, as illustrated in FIG. 13A, the cracks Cr may occur near the edge 55d1 of the fourth surface portion 55d included in the second external electrode 55. If this crack Cr reaches the internal electrode 82, there is a possibility that the internal electrode 82 and the second external electrode 55 may be short-circuited. However, in this embodiment, the notch 82b1 is provided and the gap S2 is formed, thereby suppressing the occurrence of such short-circuits.

Similarly, depending on the environment in which the first multilayer ceramic capacitor 81 is used, the cracks Cr may occur near the edge 54d1 of the fourth surface portion 54d included in the first external electrode 54, as illustrated in FIG. 13B. If this crack Cr reaches the internal electrode 83, there is a possibility that the internal electrode 83 and the first external electrode 54 may be short-circuited. However, in this embodiment, the notch 83b1 is provided to suppress the occurrence of such a short circuit.

The open end 82b of the internal electrode 82 has notches 82b1 at the top and bottom in the Z-axis direction. Similarly, an open end 83d of the internal electrode 83 has notches 83b1 at the top and bottom in the Z-axis direction. This makes it possible to suppress the occurrence of a short circuit as described above even when the first multilayer ceramic capacitor 81 is inverted and mounted on the printed wiring board 1.

In addition, in this embodiment in which the notches 82b1 are provided at the top and bottom in the Z-axis direction of the open end 82b, a portion sandwiched between the notches 82b1 remains along the Z-axis direction. A similar portion remains in the open end 83b. Therefore, the first multilayer ceramic capacitor 81 of this embodiment has a larger opposing area between the internal electrodes than the first multilayer ceramic capacitor 71 of the fourth embodiment. As a result, the first multilayer ceramic capacitor 81 of this embodiment can have a larger electrostatic capacity than the first multilayer ceramic capacitor 71 of the fourth embodiment.

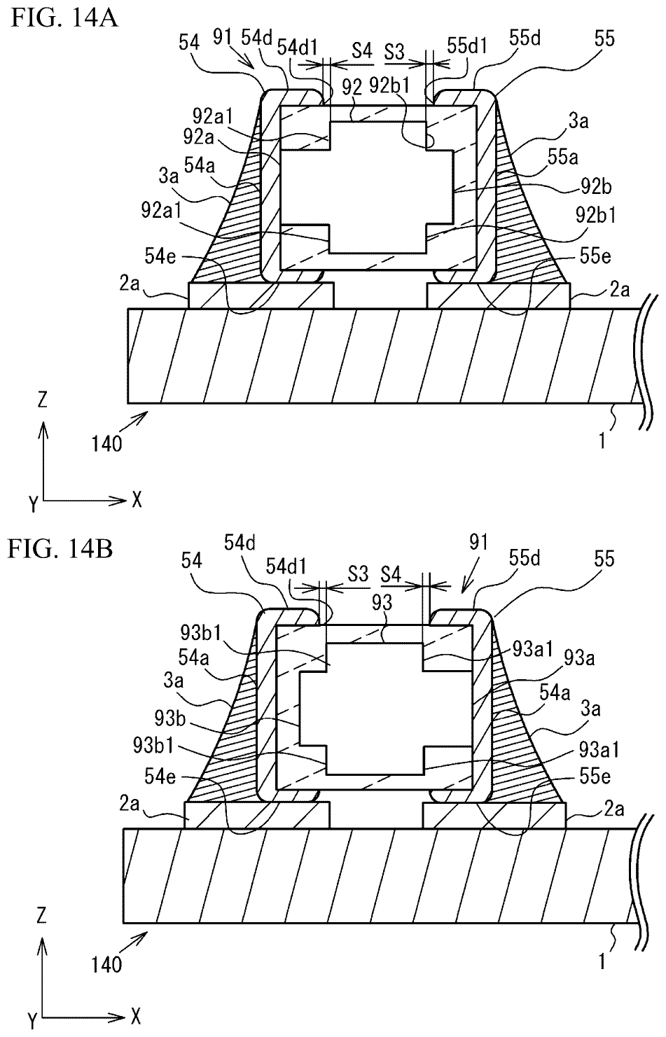

(Sixth embodiment) Next, the sixth embodiment will be described. In the sixth embodiment, instead of the first multilayer ceramic capacitor 10 illustrated in FIG. 1, a first multilayer ceramic capacitor 91 illustrated in FIG. 14A and FIG. 14B is mounted on the printed wiring board 1. Internal electrodes 92, 93 in the first multilayer ceramic capacitor 91 of the sixth embodiment are alternately arranged along the Y-axis direction so as to face each other in the Y-axis direction, similar to the first multilayer ceramic capacitor 50 of the second embodiment. FIG. 14A is a cross-sectional view of the position where the first multilayer ceramic capacitor 91 of a circuit board 140 of the sixth embodiment is mounted, and illustrates a state in which the internal electrode 92 is exposed. FIG. 14B is a cross-sectional view of the circuit board 140 of the sixth embodiment at a portion different in the width direction from FIG. 14A, and illustrates a state in which the internal electrode 93 is exposed.

«External Shape» The external shape of the first multilayer ceramic capacitor 91 is generally the same as that of the first multilayer ceramic capacitor 50 of the second embodiment. Among the components of the first multilayer ceramic capacitor 91, those components common to the first multilayer ceramic capacitor 50 of the second embodiment are given the same reference numbers in the drawings, and detailed descriptions thereof are omitted.

«Internal Structure» The first multilayer ceramic capacitor 91 has the internal electrodes 92, 93 instead of the internal electrodes 52, 53 of the first multilayer ceramic capacitor 50 of the second embodiment.

The internal electrodes 92 correspond to the first group, and each of the internal electrodes 92 has a connection end 92a connected to the first external electrode 54 and an open end 92b located on the opposite side to the connection end 92a, as illustrated in FIG. 14A. This open end 92b has a notch 92b1, similar to the first multilayer ceramic capacitor 81 of the fifth embodiment.

The internal electrodes 93 correspond to the second group, and each of the internal electrodes 93 has a connection end 93a connected to the second external electrode 55, and an open end 93b located opposite the connection end 93a, as illustrated in FIG. 14B. This open end 93b has a notch 93b1, similar to the first multilayer ceramic capacitor 81 of the fifth embodiment.

The notches 92b1, 93b1 form the gap S3, similar to the first multilayer ceramic capacitor 81 of the fifth embodiment, and can suppress the occurrence of a short circuit in the first multilayer ceramic capacitor 91.

The first multilayer ceramic capacitor 91 of this embodiment has the notches 92b1, 93b1 formed in the open ends 92b, 93b, as well as notches 92a1, 93a1 formed in the connection ends 92a, 93a. The connection ends 92a, 93a have the notches 92a1, 93a1 at the top and bottom in the Z-axis direction, respectively. In other words, when the first multilayer ceramic capacitor 91 is mounted on the printed wiring board 1, the connection ends 92a, 93a have the notches 92a1, 93a1 at the edge farthest from the printed wiring board 1 and the edge closest to the printed wiring board 1.

It is known that when a multilayer ceramic capacitor has a ceramic body having an internal electrode mainly composed of Ni and an external electrode mainly composed of Cu, a phenomenon occurs in which Cu in the external electrode diffuses into the internal electrode while reacting with Ni. When this phenomenon occurs, the end of the internal electrode close to the external electrode expands in the ceramic body. When the end of the internal electrode expands, it can cause cracks to occur or expand within the ceramic body.

Therefore, by providing the notches 92a1, 93a1 as in this embodiment, gaps S4 are formed, which makes it possible to suppress the diffusion of Cu from the external electrodes 54,55 to the internal electrodes 92, 93. As a result, the occurrence and expansion of cracks is suppressed.

### Examples

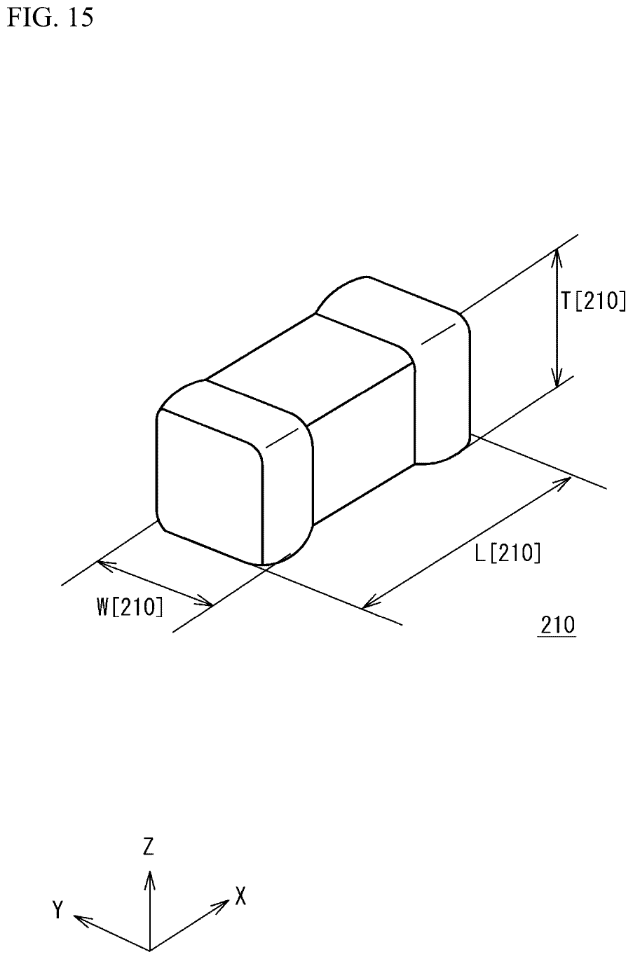

(Example 1) Next, Example 1 will be described. In Example 1, the dimensions of each part of the first multilayer ceramic capacitor 10 and the second multilayer ceramic capacitor 30 in the circuit board 100 of the first embodiment are set to the values shown below. The combinations of the first multilayer ceramic capacitor 10 and the second multilayer ceramic capacitor 30 were five patterns, patterns 1 to 5. In addition, three patterns, Comparative Example 1 to Comparative Example 3, were prepared for the comparative example. In the comparative example, instead of the first multilayer ceramic capacitor 10, a first multilayer ceramic capacitor 210 of the comparative example illustrated in FIG. 15 is mounted on the printed wiring board 1.

### <Pattern 1>

### The First Multilayer Ceramic Capacitor 10:

Length L[10]: 1.0 mm, Width W[10]: 0.5 mm, Height T[10]: 0.8 mm, Mounting area MA[10]: 0.5 mm²

### The Second Multilayer Ceramic Capacitor 30:

Length L[30]: 3.2 mm, Width W[30]: 1.6 mm, Height T[30]: 1.6 mm, Mounting area MA[30]: 5.12 mm²

T[10]/W[10] in the pattern 1 is 1.6, which satisfies the condition of the first multilayer ceramic capacitor 10 of the first embodiment that T[10] is 1.3 times or more W[10]. In addition, the mounting area MA[10]/the mounting area MA[30] is approximately 0.098, which satisfies the condition that mounting area MA[10] is 1/10 or less of the mounting area MA[30].

### <Pattern 2>

### The First Multilayer Ceramic Capacitor 10:

Length L[10]: 0.6 mm, Width W[10]: 0.3 mm, Height T[10]: 0.5 mm, Mounting area MA[10]: 0.18 mm²

### The Second Multilayer Ceramic Capacitor 30:

Length L[30]: 2.0 mm, Width W[30]: 1.25 mm, Height T[30]: 1.25 mm, Mounting area MA[30]: 2.5 mm²

T[10]/W[10] in the pattern 2 is approximately 1.7, which satisfies the condition of the first multilayer ceramic capacitor 10 of the first embodiment that T[10] is 1.3 times or more W[10]. In addition, the mounting area MA[10]/the mounting area MA[30] is 0.072, which satisfies the condition that the mounting area MA[10] is 1/10 or less of the mounting area MA[30].

### <Pattern 3>

### The First Multilayer Ceramic Capacitor 10:

Length L[10]: 0.4 mm, Width W[10]: 0.2 mm, Height T[10]: 0.3 mm, Mounting area MA[10]: 0.08 mm²

### The Second Multilayer Ceramic Capacitor 30:

Length L[30]: 1.6 mm, Width W[30]: 0.8 mm, Height T[30]: 0.8 mm, Mounting area MA[30]: 1.28 mm²

T[10]/W[10] in the pattern 3 is approximately 1.5, which satisfies the condition of the first multilayer ceramic capacitor 10 of the first embodiment that T[10] is 1.3 times or more W[10]. Furthermore, the mounting area MA[10]/the mounting area MA[30] is 0.0625, which satisfies the condition that mounting area MA[10] is 1/10 or less of mounting area MA[30].

### <Pattern 4>

### The First Multilayer Ceramic Capacitor 10:

Length L[10]: 0.6 mm, Width W[10]: 0.3 mm, Height T[10]: 0.4 mm, Mounting area MA[10]: 0.18 mm²

### The Second Multilayer Ceramic Capacitor 30:

Length L[30]: 2.0 mm, Width W[30]: 1.25 mm, Height T[30]: 1.25 mm, Mounting area MA[30]: 2.5 mm²

T[10]/W[10] in the pattern 4 is approximately 1.33, which satisfies the condition of the first multilayer ceramic capacitor 10 of the first embodiment that T[10] is 1.3 times or more W[10]. In addition, the mounting area MA[10]/the mounting area MA[30] is 0.072, which satisfies the condition that the mounting area MA[10] is 1/10 or less of the mounting area MA[30].

### <Pattern 5>

### The First Multilayer Ceramic Capacitor 10:

Length L[10]: 1.0 mm, Width W[10]: 0.5 mm, Height T[10]: 0.7 mm, Mounting area MA[10]: 0.5 mm²

### The Second Multilayer Ceramic Capacitor 30:

Length L[30]: 3.2 mm, Width W[30]: 1.6 mm, Height T[30]: 1.6 mm, Mounting area MA[30]: 5.12 mm²

T[10]/W[10] in the pattern 5 is 1.4, which satisfies the condition of the first multilayer ceramic capacitor 10 of the first embodiment that T[10] is 1.3 times or more W[10]. Furthermore, the mounting area MA[10]/the mounting area MA[30] is approximately 0.098, which satisfies the condition that mounting area MA[10] is 1/10 or less of mounting area MA[30].

Next, the dimensions of each part of Comparative Examples 1 to 3 are shown. The dimensions of each part of comparative example multilayer ceramic capacitor 210 are expressed as a length L[210], a width W[210], and a height T[210], as illustrated in FIG. 15.

### Comparative Example 1

### The First Multilayer Ceramic Capacitor 210:

Length L[210]: 1.0 mm, Width W[210]: 0.5 mm, Height T[210]: 0.5 mm, Mounting area MA[210]: 0.5 mm²

### The Second Multilayer Ceramic Capacitor 30:

Length L[30]: 3.2 mm, Width W[30]: 1.6 mm, Height T[30]: 1.6 mm, Mounting area MA[30]: 5.12 mm²

T[210]/W[210] in Comparative Example 1 is 1.0. In this respect, Comparative Example 1 does not satisfy the condition of the first multilayer ceramic capacitor 10 of the first embodiment that the height T is 1.3 times or more the width W. The mounting area MA[210]/the mounting area MA[30] is approximately 0.098, which satisfies the conditions for the mounting area of the first and second multilayer ceramic capacitors.

### Comparative Example 2

### The First Multilayer Ceramic Capacitor 210:

Length L[210]: 0.6 mm, Width W[210]: 0.3 mm, Height T[210]: 0.3 mm, Mounting area MA[210]: 0.18 mm²

### The Second Multilayer Ceramic Capacitor 30:

Length L[30]: 2.0 mm, Width W[30]: 1.25 mm, Height T[30]: 1.25 mm, Mounting area MA[30]: 2.5 mm²

T[210]/W[210] in Comparative Example 2 is 1.0. In this respect, Comparative Example 2 does not satisfy the condition of the first multilayer ceramic capacitor 10 of the first embodiment that the height T is 1.3 times or more the width W. The mounting area MA[210]/the mounting area MA[30] is 0.072, and in this respect, the condition regarding the mounting area of the first multilayer ceramic capacitor and the second multilayer ceramic capacitor is satisfied.

### Comparative Example 3

### The First Multilayer Ceramic Capacitor 210:

Length L[210]: 0.4 mm, Width W[210]: 0.2 mm, Height T[210]: 0.2 mm, Mounting area MA[210]: 0.08 mm²

### The Second Multilayer Ceramic Capacitor 30:

Length L[30]: 1.6 mm, Width W[30]: 0.8 mm, Height T[30]: 0.8 mm, Mounting area MA[30]: 1.28 mm²

T[210]/W[210] in Comparative Example 3 is 1.0. In this respect, Comparative Example 3 does not satisfy the condition of the first multilayer ceramic capacitor 10 of the first embodiment that the height T is 1.3 times or more the width W. The mounting area MA[210]/the mounting area MA[30] is 0.0625, and in this respect, the condition regarding the mounting area of the first multilayer ceramic capacitor and the second multilayer ceramic capacitor is satisfied.

[Test method] 500 samples each of the patterns 1 to 5 of the first embodiment and Comparative Examples 1 to 3 were prepared and subjected to a heat cycle test. In the heat cycle test, each sample was placed in a thermostatic chamber, heated to 85° C. and held there for 30 minutes, then cooled to −55° C. and held there for 30 minutes, and this was counted as one cycle, and 1000 cycles were repeated.

After the heat cycle test, each sample used in the test was polished and the cross section was observed under a microscope to check for the presence or absence of cracks.

[Test Results] No cracks were found in any of the samples of patterns 1 to 3 of Example 1. In samples of the patterns 4 and 5 of Example 1, cracks were found in one sample each, all in small-sized electronic components.

Cracks were found in nine samples in Comparative Example 1, 15 samples in Comparative Example 2, and 20 samples in Comparative Example 3, all in the small-sized first multilayer ceramic capacitor 210.

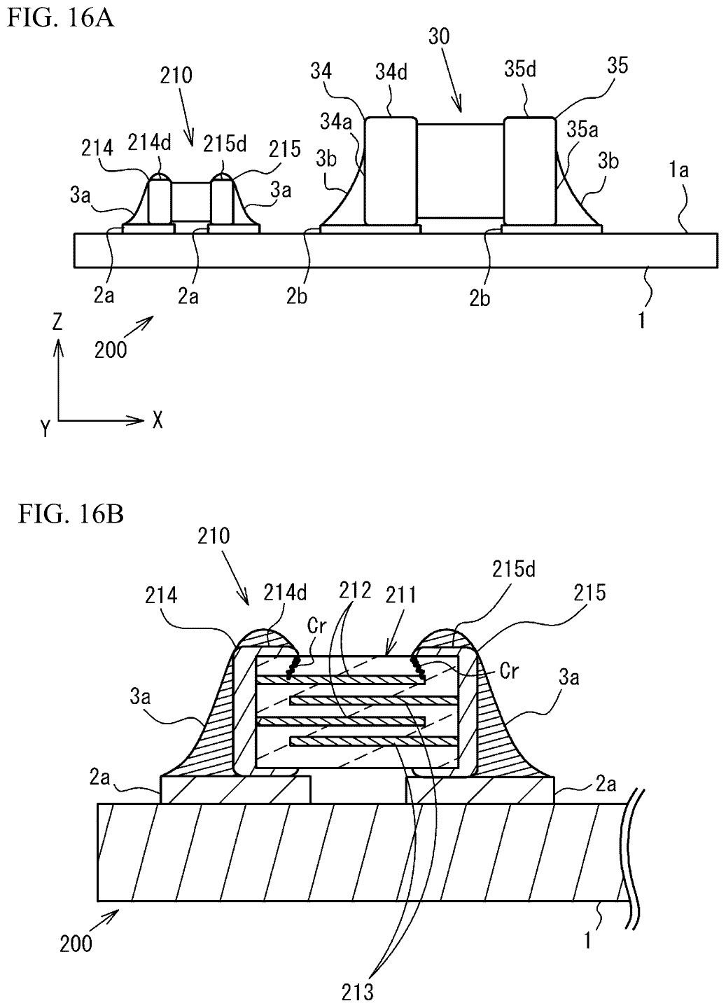

Now, with reference to FIG. 16A and FIG. 16B, we will consider why cracks occurred more frequently in the samples of the comparative example. FIG. 16A is a side view of a circuit board 200 of the comparative example, and FIG. 16B is a cross-sectional view of the position where the first multilayer ceramic capacitor 210 is mounted on the circuit board 200 of the comparative example.

With reference to FIG. 16B, the first multilayer ceramic capacitor 210 of the comparative example has a ceramic body 211, a first external electrode 214, and a second external electrode 215, similar to the first multilayer ceramic capacitor 10 of the first embodiment. Internal electrodes 212 and 213 are provided within the ceramic body 211. The first external electrode 214 has a fourth surface portion 214d, and the second external electrode 215 has a fourth surface portion 215d. The first multilayer ceramic capacitor 210 of the comparative example is mounted on the printed wiring board 1 by being placed on the land 2a and fixed by the solder fillet 3a. However, the first multilayer ceramic capacitor 210 of the comparative example has a smaller height T and is shorter than the first multilayer ceramic capacitor 10 of the first embodiment. Therefore, the solder fillet 3a reaches the fourth surface portions 214d, 215d, and the fourth surface portions 214d, 215d are covered by the solder fillet 3a.

If the solder fillet 3a reaches the fourth surface portions 214d, 215d, the vibration of the printed wiring board 1 is propagated to the vicinity of the boundary between the fourth surface portions 214d, 215d and the ceramic body 211. As a result, it is considered that the cracks Cr are more likely to occur in the comparative example.

According to the first embodiment, the occurrence of the cracks Cr is suppressed by satisfying the condition that T[10] is 1.3 times or more W[10] under the condition that the mounting area MA[10] is 1/10 or less of the mounting area MA[30].

(Example 2) Next, Example 2 will be described. In Example 2, the same combinations of the patterns 1 to 5 as in Example 1 were prepared for the dimensions of the first multilayer ceramic capacitor 50 and the dimensions of the second multilayer ceramic capacitor 30. Then, tests were performed for each pattern in the same manner as in Example 1.

As a result, no cracks were found in any of the samples of the patterns 1 to 3 of Example 2. In the samples of the patterns 4 and 5 of Example 2, cracks were found in one sample each, in small-sized electronic components. In this way, Example 2 obtained results similar to those of Example 1. This is thought to be because whether or not cracks occur is related to the external shape and dimensions of the first multilayer ceramic capacitor 50. In other words, in Example 2, the combination of the dimensions of the first multilayer ceramic capacitor 50 and the second multilayer ceramic capacitor 30 is the same as in Example 1. Therefore, it is thought that the test results of Example 2 were generally the same as those of Example 1.

The electrostatic capacity was measured for the first multilayer ceramic capacitor 10 of Example 1 and the first multilayer ceramic capacitor 50 of Example 2. The electrostatic capacity was measured for the patterns 1 to 5 of each Example. The measurements were performed on 100 samples of each Example, at 1 kHz and 0.5 Vrms. The average electrostatic capacity was then calculated. As a result, in the first multilayer ceramic capacitor 10 of Example 1, the electrostatic capacity was within a range of ±10 to 20% of the average value. In contrast, in the first multilayer ceramic capacitor 50 of Example 2, the electrostatic capacity was within a range of ±5% of the average value. In other words, the first multilayer ceramic capacitor 50 of Example 2 had a smaller decrease in electrostatic capacity relative to the design value. This is believed to be due to the difference in the stack form of the internal electrodes.

In the above embodiments, a multilayer ceramic capacitor has been described as an example of a multilayer ceramic electronic component, but the present invention is not limited to this. For example, the configuration of each of the above embodiments can also be applied to other multilayer ceramic electronic components, such as varistors and thermistors.

Although the embodiments of the present invention have been described in detail, it is to be understood that the various change, substitutions, and alterations could be made hereto without departing from the spirit and scope of the invention.

What is claimed is:

1. A circuit board comprising:
a board;
a multilayer ceramic electronic component mounted on a mounting surface of the board; and
an electronic component that is adjacent to the multilayer ceramic electronic component and mounted on the mounting surface of the board,
wherein a mounting area of the multilayer ceramic electronic component on the board is 1/10 or less of a mounting area of the electronic component on the board, and
wherein a dimension of the multilayer ceramic electronic component in a direction along a first axis orthogonal to the mounting surface is 1.3 times or more a dimension of the multilayer ceramic electronic component in a direction along a second axis orthogonal to the first axis.

2. The circuit board as claimed in claim 1,
wherein the dimension of the multilayer ceramic electronic component in the direction along the first axis is 1.5 times or more the dimension of the multilayer ceramic electronic component in the direction along the second axis.

3. The circuit board as claimed in claim 1,
wherein internal electrodes provided in a ceramic body of the multilayer ceramic electronic component are stacked in the direction along the first axis so as to face each other in the direction along the first axis.

4. The circuit board as claimed in claim 3,
wherein the ceramic body of the multilayer ceramic electronic component has a pair of main faces orthogonal to the direction along the first axis, a pair of side faces orthogonal to the direction along the second axis, and a pair of end faces orthogonal to a direction along a third axis that is orthogonal to the first axis and the second axis,
wherein the multilayer ceramic electronic component includes first and second external electrodes provided on the pair of end faces, respectively, and each having an extension portion extending toward the pair of main faces, and
wherein of the internal electrodes provided in the multilayer ceramic electronic component, at least the internal electrode located at a position farthest from the board has a connection end connected to the first external electrode and an open end located opposite the connection end, and the open end is located closer to the first external electrode than an edge of the extension portion extended from the second external electrode.

5. The circuit board as claimed in claim 1,
wherein the internal electrodes provided in the ceramic body of the multilayer ceramic electronic component are stacked in the direction along the second axis so as to face each other in the direction along the second axis.

6. The circuit board as claimed in claim 5,
wherein the ceramic body of the multilayer ceramic electronic component has a pair of main faces orthogonal to the first axis, a pair of side faces orthogonal to the second axis, and a pair of end faces orthogonal to a third axis orthogonal to the first axis and the second axis,
wherein the multilayer ceramic electronic component includes first and second external electrodes provided on the pair of end faces, respectively, and each having an extension portion extending toward the pair of main faces,
wherein the internal electrodes of the multilayer ceramic electronic component include a first group connected to the first external electrode and a second group connected to the second external electrode,
wherein the internal electrodes included in the first group have a connection end connected to the first external electrode and an open end located opposite the connection end, and the open end is located closer to the first external electrode than an edge of the extension portion extended from the second external electrode, and
wherein the internal electrodes included in the second group have a connection end connected to the second external electrode and an open end located opposite the connection end, and the open end is located closer to the second external electrode than an edge of the extension portion extended from the first external electrode.

7. The circuit board as claimed in claim 5,
wherein the ceramic body of the multilayer ceramic electronic component has a pair of main faces orthogonal to the first axis, a pair of side faces orthogonal to the second axis, and a pair of end faces orthogonal to a third axis orthogonal to the first axis and the second axis,
wherein the multilayer ceramic electronic component includes first and second external electrodes respectively provided on the pair of end faces and each having an extension extending toward the pair of main faces,
wherein the internal electrodes of the multilayer ceramic electronic component include a first group connected to the first external electrode and a second group connected to the second external electrode,
wherein the internal electrodes included in the first group have a connection end connected to the first external electrode and an open end located opposite the connection end, and the open end has a notch recessed from an edge farthest from the board toward the board, and
wherein the internal electrodes included in the second group have a connection end connected to the second external electrode and an open end located opposite the connection end, and the open end has a notch recessed from an edge farthest from the board toward the board.

8. The circuit board as claimed in claim 5,
wherein the ceramic body of the multilayer ceramic electronic component has a pair of main faces orthogonal to the first axis, a pair of side faces orthogonal to the second axis, and a pair of end faces orthogonal to a third axis orthogonal to the first axis and the second axis,
wherein the multilayer ceramic electronic component includes first and second external electrodes provided on the pair of end faces, respectively, and each having an extension extending toward the pair of main faces,
wherein the internal electrodes of the multilayer ceramic electronic component include a first group connected to the first external electrode and a second group connected to the second external electrode,
wherein the internal electrodes included in the first group have a connection end connected to the first external electrode and an open end located opposite the connection end, and the connection end has a notch recessed from an edge farthest from the board toward the board, and a notch recessed from an edge closest to the board toward the board, and
wherein the internal electrodes included in the second group have a connection end connected to the second external electrode and an open end located opposite the connection end, and the connection end has a notch that is recessed from an edge farthest from the board toward the board, and a notch that is recessed from an edge closest to the board toward the board.
